(19) United States
(12) Patent Application Publication
(10) Pub. No.: US 2015/0196988 A1
(43) Pub. Date: Jul. 16, 2015

(54) POLISH APPARATUS AND POLISH METHOD

(71) Applicant: KABUSHIKI KAISHA TOSHIBA, Minato-ku (JP)

(72) Inventor: Takashi WATANABE, Yokkaichi (JP)

(73) Assignee: KABUSHIKI KAISHA TOSHIBA, Minato-ku (JP)

(21) Appl. No.: 14/301,713

(22) Filed: Jun. 11, 2014

(30) Foreign Application Priority Data
Jan. 10, 2014 (JP) 2014-003254

(51) Int. Cl. B24B 37/015; B24B 37/34; H01L 21/304; B24B 49/14; B24B 55/03; B24B 37/04; B24B 49/12

(52) U.S. Cl. CPC B24B 37/015; B24B 37/042; B24B 37/34; B24B 49/12; B24B 49/14; B24B 55/03; H01L 21/304

(57) ABSTRACT

A polish apparatus including a polish pad including a polish surface configured to contact a polish object; and a coolant injector configured to inject a coolant to the polish surface and cool the polish pad by a vaporization heat.

### CROSS-REFERENCE TO RELATED APPLICATION(S)

This application is based upon and claims the benefit of priority from Japanese Patent Application No. 2014-003254, filed on, Jan. 10, 2014 the entire contents of which are incorporated herein by reference.

### FIELD

Embodiments disclosed herein generally relate to a polish apparatus and a polish method.

### BACKGROUND

Chemical mechanical polishing (CMP) is frequently used in semiconductor device manufacturing. Because the speed of chemical reaction in CMP varies with temperature, the surface of the polish pad being placed in contact with the polish object such as a wafer needs to be controlled to appropriate temperatures. When polishing a silicon oxide film for example, the polish rate tends to increase as the surface temperature of the polish pad becomes lower. When polishing a metal film on the other hand, the polish rate tends to increase as the surface temperature of the polish pad becomes higher because chemical reaction is facilitated at high temperatures. However, corrosion of the metal film is also facilitated at high temperatures. Thus, metal films may be polished efficiently by varying the surface temperature of the polish pad from the higher side to the lower side during the polishing process.

Neither air blowing the polish pad surface nor cooling the polish pad surface with a refrigerant cooler achieves rapid cooling of the polish pad surface because of poor cooling efficiency. Further, cooling the polish pad surface with water or aqueous solvent causes slurry dilution or variation of polish characteristics.

### BRIEF DESCRIPTION OF THE DRAWINGS

FIG. 1 pertains to a first embodiment and schematically illustrates one example of a polish apparatus.

FIG. 2 is a chart indicating examples of coolants used in the polish apparatus of the first embodiment.

FIGS. 3A, 3B, and 3C are schematic examples of cross-sectional views of a wafer to be polished.

FIG. 4 pertains to a second embodiment and schematically illustrates one example of a polish apparatus.

FIG. 5 pertains to a third embodiment and schematically illustrates one example of a polish apparatus.

FIG. 6 pertains to a fourth embodiment and schematically illustrates one example of a polish apparatus.

### DESCRIPTION

In one embodiment, a polish apparatus includes a polish pad including a polish surface configured to contact a polish object; and a coolant injector configured to inject a coolant to the polish surface and cool the polish pad by a vaporization heat.

In one embodiment, a polishing method includes polishing a polish object with a polish surface of a polish pad; and cooling the polish surface of the polish pad by a vaporization heat of a coolant, the cooling being performed at least for one time period during the polishing.

### EMBODIMENTS

Embodiments are described hereinafter with references to the accompanying drawings. Elements that are identical or similar across the embodiments are identified with identical or similar reference symbols and may not be re-described.

### First Embodiment

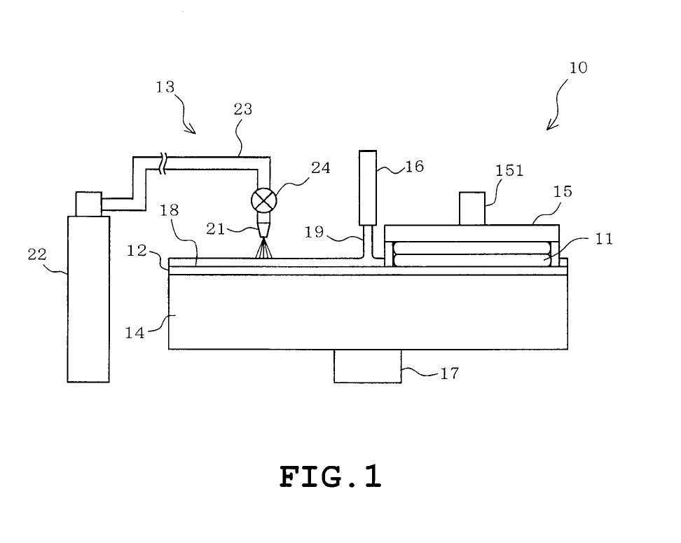

First, a brief description will be given on a polish apparatus of a first embodiment. As shown in FIG. 1, polish apparatus 10 of the first embodiment is used for polishing a polish object such as wafer 11 by CMP (Chemical Mechanical Polishing) in semiconductor device manufacturing. Polish apparatus 10 is provided with polish pad 12 and coolant injector 13. Polish apparatus 10 is further provided with table 14, polish head 15, and slurry dispenser 16. Polish pad 12 is shaped like a circular disc and is made of, for example, a foamed resin. Polish pad 12 is provided above table 14 so as to face polish head 15. Table 14 is driven in rotation with the overlying polish pad 12 by drive unit 17. Polish pad 12 has polish surface 18 located at its upper end surface, with respect to the gravitational direction, so as to face polish head 15.

Polish head 15 is disposed above table 14 so as to face polish pad 12 provided over table 14. Polish head 15 holds the polish object, one example of which is wafer 11, placed in its inner side. Polish head 15 applies force on wafer 11 so that wafer 11 is not only held by polish head 15 but also pressed downward against polish head 18 of polish pad 12. Polish head 15 is driven in rotation by drive unit 151.

Slurry dispenser 16 supplies slurry 19, including polishing agent and water, to polish head 15 of polish surface 18. Slurry 19 supplied from slurry dispenser 16 spreads into the gap between wafer 11 held by polish head 15 and polish surface 18 of polish pad 12. Wafer 11 being held by polish head 15 is pressed against polish pad 12 with appropriate force. The surface of wafer 11 is thus polished through contact with polish surface 18 of polish pad 12.

Coolant injector 13 is provided with injection nozzle 21, coolant tank 22, coolant piping 23, and valve 24. Injection nozzle 21 is disposed so as to face polish surface 18 of polish pad 12. Coolant tank 22 stores the coolant. Coolant piping 23 connects injection nozzle 21 with coolant tank 22. Thus, the coolant stored in coolant tank 22 is supplied to injection nozzle 21 through coolant piping 23. In one embodiment, the coolant is stored in coolant tank 22 in the form of a liquid. The coolant is injected onto polish surface 18 of polish pad 12 from injection nozzle 21. The temperature of polish surface 18, being subjected to contact with wafer 11 and being polished, is higher than room temperature. Thus, the coolant injected onto polish surface 18 is vaporized upon injection from injection nozzle 21 or upon contact with polish surface 18. As a result, the coolant cools polish surface 18 by the vaporization heat produced when the coolant is vaporized. As described above, the coolant is vaporized by being injected onto polish surface 18 of polish pad 12 and cools polish surface 18 by the vaporization heat. Valve 24 is provided on coolant piping 23 for opening/closing coolant piping 23. Thus, the coolant injection from injection nozzle 21 is initiated or interrupted by valve 24. Valve 24 may be structurally integral with injection nozzle 21.

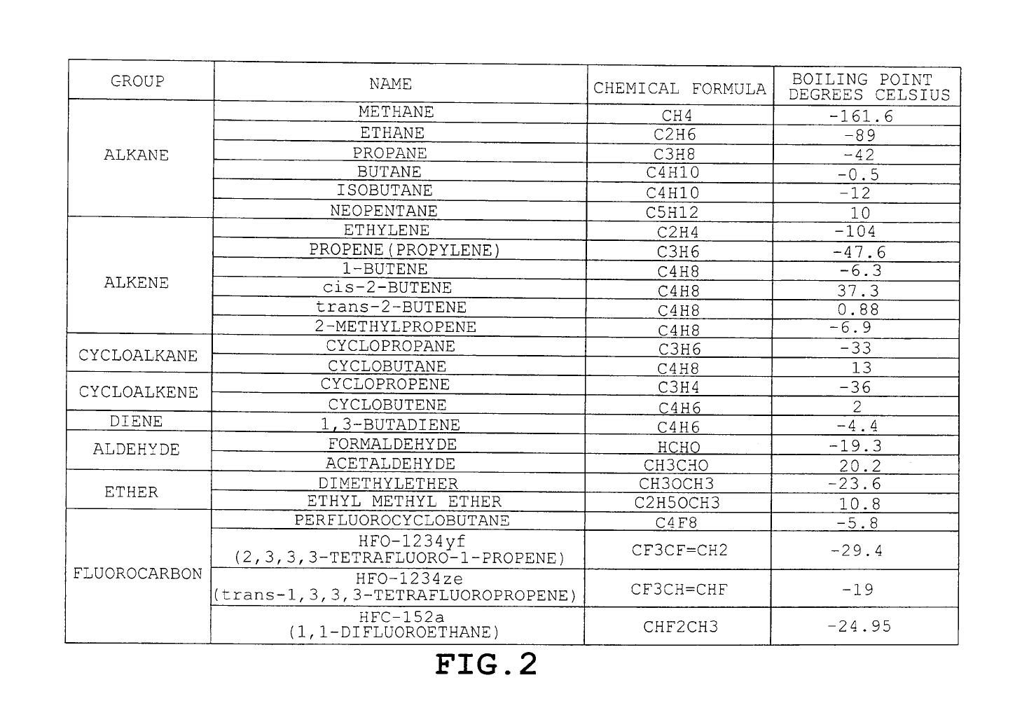

The boiling point of the coolant is preferably 25 degrees Celsius or less since the coolant cools polish surface 18 using the vaporization heat. Any coolant may be employed depending upon the polishing conditions being applied such as: the room temperature of the facility performing the polishing of wafer 11, the type of polish object, and the rotational speed of polish pad 12. Examples of coolants may be materials that possess appropriate boiling points or amount of vaporization heat with respect to the amount of heat produced during polishing or the desired cooling speed. Coolants that meet these conditions are preferably selected from the examples listed in the chart of FIG. 2 which include alkanes, cycloalkanes, fluorocarbons, alkenes, cycloalkenes, dienes, and aldehydes. Among these types of materials, it is preferable to employ materials that have carbon numbers ranging from 3 to 5. The coolant injected onto polish surface 18 contacts slurry 19. When the coolant dissolves into water, a constituent of slurry 19, the characteristics of slurry 19 may be varied. The variation of slurry 19 characteristics may lead to variation of polish characteristics. Thus, it is preferable to select hydrophobic materials as coolants from the foregoing types of materials.

Next, a description will be given on one example of a polish process performed using the above described polish apparatus 10.

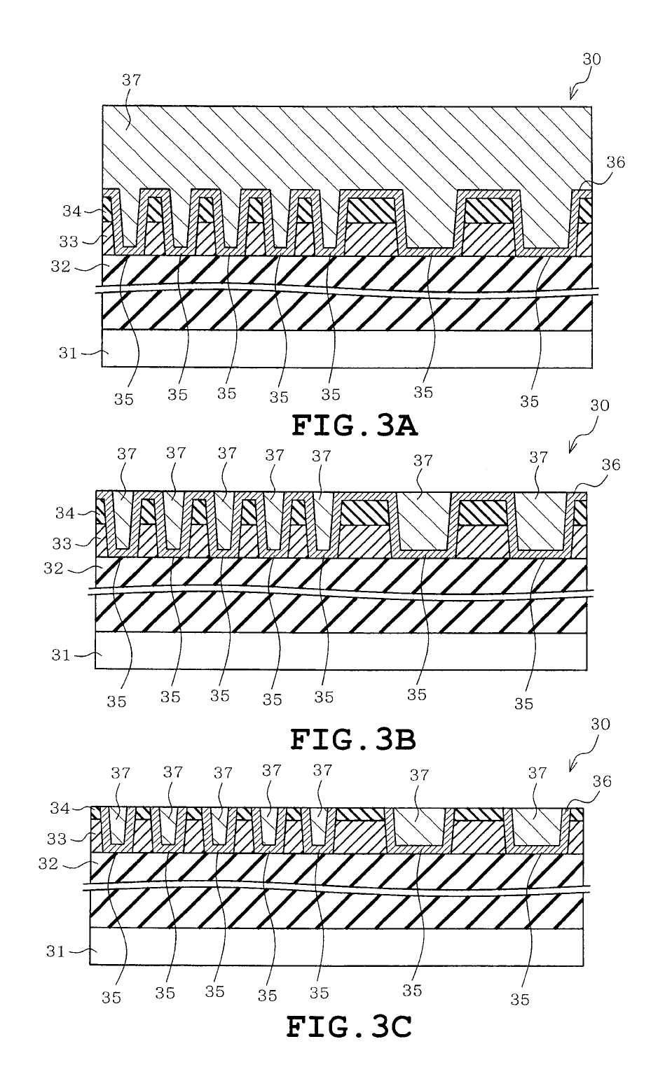

As illustrated in FIG. 3A, wafer 30 being polished is typically semiconductor substrate 31 having elements such as transistors and memory cells formed on it. The elements formed on wafer 30 are covered by insulating film 32 formed of a silicon oxide film for example and insulating film 32 is in turn covered by etch stopper film 33 formed of a silicon nitride film for example. Etch stopper film 33 is covered by insulating film 34 formed of a silicon oxide film for example. Wiring trenches 35, connecting to the elements not illustrated, are formed into etch stopper film 33 and insulating film 34. Barrier metal film 36 formed of a Ti film for example is lined along wiring trenches 35, and wiring trenches 35 are filled with Cu film 37 serving as a wiring material.

Wafer 30 illustrated in FIG. 3A is subjected to a polish process in which Cu film 37 is selectively polished until barrier metal film 36 is exposed as illustrated in FIG. 3B. The polishing of Cu film 37 is defined as a first polishing phase generally referred to as a Cu bulk polishing. Wafer 30 illustrated in FIG. 3B is further subjected to a polish process in which Cu film 37, barrier metal film 36, and insulating film 34 are polished as illustrated in FIG. 3C. As a result, Cu films 37 filled in each of wiring trenches 35 become isolated from one another. The polishing of Cu film 37, barrier metal film 36, and insulating film 34 is defined as a second polishing phase generally referred to as a barrier metal polishing.

In the first embodiment, a description will be given on the polishing process through an example of the first polishing phase also referred to as the Cu bulk polishing in which wafer 30 illustrated in FIG. 3A results in the state illustrated in FIG. 3B. When wafer 30 is polished using polish pad 12, the temperature of polish surface 18 of polish pad 12 is elevated by friction heat. Generally, the polish speed of Cu film 37 is accelerated as the temperature becomes higher. On the other hand, when barrier metal film 36 is exposed with progression of Cu film 37 polishing, galvanic corrosion of Cu film 37 serving as a wiring is facilitated with temperature elevation. Thus, when polishing Cu film 37, it is required to polish Cu film 37 at relatively high temperatures in the initial phase and then proceed to cool polish surface 18 of polish pad 12 before barrier metal film 36 is exposed.

Thus, in the first embodiment, wafer 30 is polished without coolant injection for a specific period after polish start. As a result, the temperature of polish surface 18 is elevated by the heat produced by the friction between polish pad 12 and wafer 30, thereby facilitating the polishing of Cu film 37. Then, coolant is injected on polish surface 18 of polish pad 12 after the lapse of the specific period. The amount and the time period (duration) of coolant injection are controlled so that polish surface 18 does not exceed the predetermined temperature. The temperature of polish surface 18 may be monitored for example by a radiation thermometer. As a result, polish surface 18 does not exceed the predetermined temperature before barrier metal film 36 is exposed. Thus, the corrosion of Cu film 37 serving as wirings is inhibited.

In the above described first embodiment, the coolant is injected onto polish surface 18 from injection nozzle 21. The injected coolant vaporizes upon injection from injection nozzle 21 or upon contact with polish surface 18. Thus, the vaporization heat of the coolant cools polish surface 18 and lowers the temperature of polish surface 18. High cooling efficiency is achieved because the coolant cools polish surface 18 directly. As a result, polish surface 18 of polish pad 12 can be cooled rapidly by the coolant. This provides precise polish conditions, including precisely controlled temperature, for various types of polish objects.

Further in the first embodiment, selection of hydrophobic materials is provided to serve as the coolant to prevent the coolant from dissolving into water, a constituent of slurry 19. As the coolant does not dissolve into slurry 19, the characteristics of slurry 19 remain unchanged. This means that there will be no elevation of boiling points of the coolant and water and thus, no degradation of vaporizing efficiency. As a result, it is possible to maintain a high cooling efficiency and achieve precise polish conditions for different types of polish objects.

In the first embodiment, the coolant is injected onto polish surface 18 of polish pad 12 at the appropriate timing within the polish process to vary the temperature of polish surface 18 depending upon the polish conditions. For example, when polishing needs to progress through a relatively high temperature zone and then to a relatively low temperature zone, the temperature of polish surface 18 is rapidly lowered by coolant injection. As a result, it is possible to achieve precise polish conditions for different types of polish objects.

### Second Embodiment

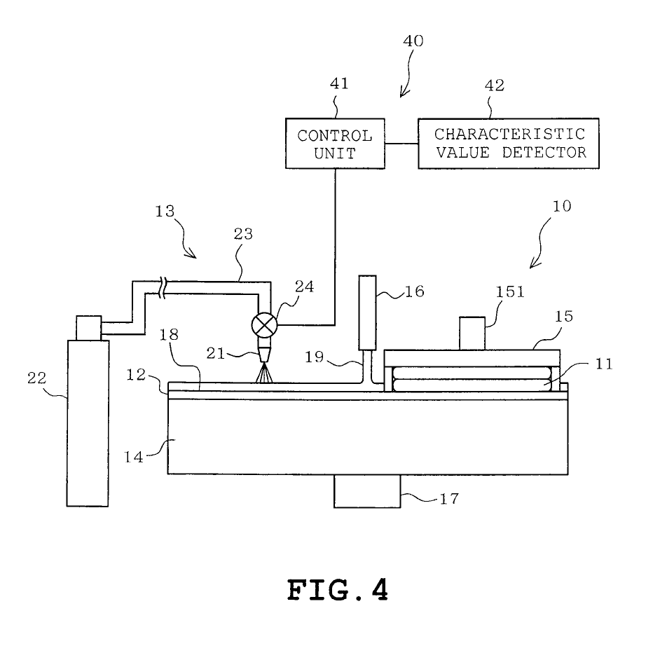

FIG. 4 illustrates a polish apparatus of a second embodiment.

Polish apparatus 10 of the second embodiment illustrated in FIG. 4 is provided with coolant injection controller 40 in addition to the components described in the first embodiment. Coolant injection controller 40 is configured by valve 24 described earlier for opening/closing coolant piping 23 and control unit 41. Control unit 41 is configured by a microcomputer including a CPU, a ROM, and a RAM for example. Control unit 41 controls the opening/closing of coolant piping 23 via valve 24 based on a computer program stored in the ROM. Valve 24 may be configured by a solenoid valve for example which opens/closes coolant piping 23 based on control signals given by control unit 41. The amount and period of coolant injection from injection nozzle 21 is controlled in the above described manner by opening/closing coolant piping 23 by valve 24.

Polish apparatus 10 of the second embodiment is provided with characteristic value detector 42. Characteristic value detector 42 detects characteristic value(s) that varies as the polishing of the polish object progresses. Characteristic value detector 42 outputs the detected characteristic value to control unit 41 in the form of an electric signal. Control unit 41 controls valve 24 based on the characteristic value detected by characteristic value detector 42, and thereby controls the amount and period of coolant injection. Thus, the temperature of polish surface 18 of polish pad 12 is controlled to precisely conform to the polish conditions through coolant injected in the appropriate timing, for the appropriate period, and in the appropriate amount.

Characteristic values detected by characteristic value detector 42 may include: reflection intensity and spectrum of light radiated on the surface of wafer 11 being polished; drive current of table 14 or polish head 15; and variation of magnetic field lines caused by eddy current produced when magnetic field lines are radiated on wafer 11 being polished. The above described characteristic values are detected for determining the progress of the polish process. Control unit 41 controls the amount and period of coolant injection using the characteristic values detected for determining the progress of the polish process by characteristic value detector 42. The characteristic values detected by characteristic value detector 42 are not limited to reflection intensity and spectrum of light, drive current, and magnetic field lines described above, but may also include the surface temperature of polish pad 12.

In the second embodiment described above, at least either the timing, the amount, or the period of coolant injection is specified by control unit 41 based on the characteristic values detected by characteristic value detector 42. The coolant is supplied to polish surface 18 of polish pad 12 at the appropriate timing, and further for the appropriate period, and in the appropriate amount depending upon the progress of the polish process as compared to the first embodiment in which the timing of coolant injection is preset. Thus, the temperature of polish surface 18 of polish pad 12 can be controlled more precisely to thereby obtain polish conditions of improved precision for different polish objects.

### Third Embodiment

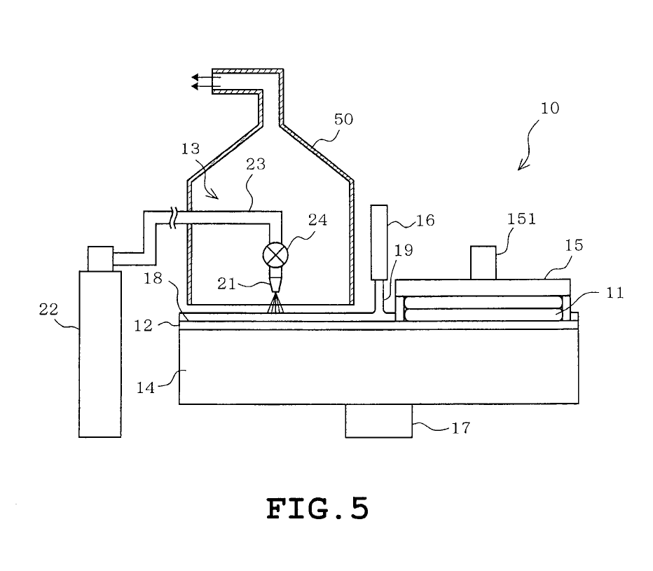

A polish apparatus of a third embodiment is illustrated in FIG. 5. Polish apparatus 10 of the third embodiment illustrated in FIG. 5 is provided with coolant collector 50. Coolant collector 50 collects the coolant injected from injection nozzle 21 and vaporized. Coolant collector 50 is shaped like a hood and covers injection nozzle 21 and the region on which the coolant is injected. As described earlier, the coolant utilizes vaporization heat for cooling polish surface 18 of polish pad 12. The coolant may be made of materials that are flammable.

In the third embodiment, the periphery of injection nozzle 21 is covered by coolant collector 50 shaped like a hood. Thus, the coolant injected from injection nozzle 21 and vaporized in the vicinity of polish surface 18 is collected by coolant collector 50. The exhaust containing the collected coolant is discharged outside the facility after being subjected to a predetermined treatment. Thus, improved safety is achieved even when flammable materials are used as the coolant.

### Fourth Embodiment

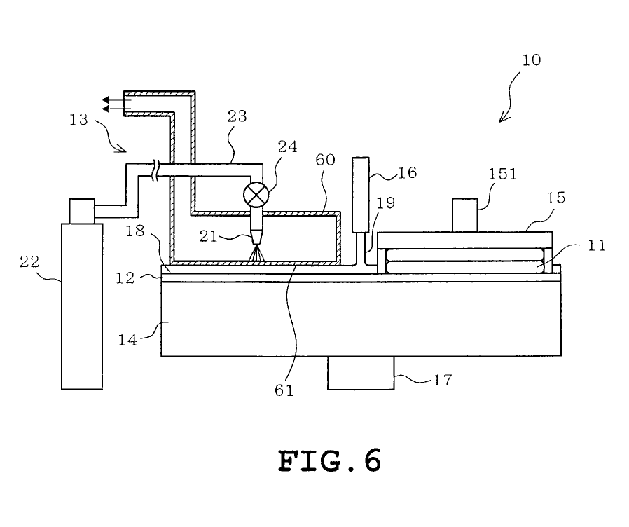

A polish apparatus of a fourth embodiment is illustrated in FIG. 6.

Polish apparatus 10 of the fourth embodiment illustrated in FIG. 6 is provided with cooling container 60. Cooling container 60 has bottom portion 61 facing polish pad 12 and contacting polish surface 18. Further, injection nozzle 21 of coolant injector 13 is provided in the inner side of cooling container 60 and injects the coolant toward bottom portion 61. Bottom portion 61 is preferably formed of materials such as a silicon carbide that have high thermal conductivity and high wear resistance and that have no risk of metal contamination. Bottom portion 61 may be formed of metals having high thermal conductivity or carbon, and the underside of bottom portion 61 facing polish surface 18 may be coated by silicon carbide or the like. The coolant injected onto bottom portion 61 is vaporized at bottom portion 61 or its vicinity and cools bottom portion 61 by vaporization heat.

Bottom portion 61 of cooling container 60 contacts polish surface 18 of polish pad 12. Because bottom portion 61 is cooled by the vaporization heat of the coolant, polish surface 18 of polish pad 12 is cooled when placed in contact with bottom portion 61. In other words, polish surface 18 is indirectly cooled by the vaporization heat of the coolant via bottom portion 61.

In the fourth embodiment, the coolant is vaporized inside cooling container 60 and cools polish surface 18 indirectly. Thus, the injected coolant does not contact polish surface 18 and slurry 19. As a result, the characteristics of the slurry will not change irrespective of the type of coolant being used. Thus, it is possible to use hydrophilic materials as the coolant.

Further, in the fourth embodiment, the vaporized coolant stays inside coolant container 60. Thus, the vaporized coolant can be collected easily. Further, it is possible to reduce the leakage of flammable coolant by confining the vaporized coolant within coolant container 60. As a result, it is possible to achieved improved safety.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A polish apparatus comprising:
a polish pad including a polish surface configured to contact a polish object; and
a coolant injector configured to inject a coolant to the polish surface and cool the polish pad by a vaporization heat.

2. A polish apparatus comprising:
a polish pad including a polish surface configured to contact a polish object;
a cooling container contacting the polish surface; and
a coolant injector configured to inject a coolant in an inner side of the cooling container and cool the polish pad by a vaporization heat via the cooling container.

3. The apparatus according to claim 1, further comprising a coolant injection controller configured to control at least either an injection amount or an injection period of the coolant injected from the coolant injector.

4. The apparatus according to claim 1, further comprising a characteristic value detector configured to detect one or more characteristic values of the polish object varying with progress of polishing of the polish object by the polish pad, and a coolant injection controller configured to control at least either an injection amount or an injection period of the coolant injected from the coolant injector based on the one or more characteristic values detected by the characteristic value detector.

5. The apparatus according to claim 4, further comprising a table configured to support and rotate the polish pad, and a polish head configured to press the polish object toward the polish surface; wherein the characteristic value detector is configured to detect at least one characteristic value selected from a group consisting of a temperature of the polish surface, a reflection intensity of light radiated on the polish surface, a spectrum of light radiated on the polish surface, a drive current of the table, a drive current of the polish head, and a variation of magnetic field line occurring at the polish object.

6. The apparatus according to claim 1, further comprising a coolant collector configured to collect the vaporized coolant.

7. The apparatus according to claim 1, wherein the coolant comprises a liquid having a boiling point of 25 degrees Celsius or less.

8. The apparatus according to claim 1, wherein the coolant comprises a compound selected from a group consisting of alkanes, cycloalkanes, ethers, fluorocarbons, alkenes, cycloalkenes, dienes, and aldehydes.

9. A polishing method comprising:
polishing a polish object with a polish surface of a polish pad; and
cooling the polish surface of the polish pad by a vaporization heat of a coolant,
the cooling being performed at least for one time period during the polishing.

10. The method according to claim 9, wherein the cooling cools the polish surface of the polish pad directly with the vaporization heat of the coolant injected onto the polish surface.

11. The method according to claim 9, wherein a cooling container is placed in contact with the polish surface of the polish pad, and wherein the cooling injects the coolant in an inner side of the cooling container and cools the polish surface indirectly with the vaporization heat of the coolant via the cooling container.

12. The method according to claim 9, wherein the cooling controls either an injection amount of the coolant or an injection period of the coolant.

13. The method according to claim 9, wherein the cooling starts or stops injection of the coolant based on one or more characteristic values of the polish object varying with progress of the polishing of the polish object by the polish pad.

14. The method according to claim 13, wherein the one or more characteristic values is at least one characteristic value selected from a group consisting of a temperature of the polish surface, a reflection intensity of light radiated on the polish surface, a spectrum of light radiated on the polish surface, a drive current of the table, a drive current of the polish head, and a variation of magnetic field line occurring at the polish object.

15. The method according to claim 9, further comprising collecting the coolant vaporized in the cooling.

16. The method according to claim 9, wherein the coolant comprises a liquid having a boiling point of 25 degrees Celsius or less.

17. The method according to claim 9, wherein the coolant comprises a compound selected from the group consisting of alkanes, cycloalkanes, ethers, fluorocarbons, alkenes, cycloalkenes, dienes, and aldehydes.
